(19) United States
(12) Patent Application Publication
(10) Pub. No.: US 2017/0110566 A1
(43) Pub. Date: Apr. 20, 2017

(54) SEMICONDUCTOR DEVICE

(71) Applicant: Panasonic Intellectual Property Management Co., Ltd., Osaka (JP)

(72) Inventor: Saichirou KANEKO, Kyoto (JP)

(21) Appl. No.: 15/395,417

(22) Filed: Dec. 30, 2016

Related U.S. Application Data
(63) Continuation of application No. PCT/JP2015/003224, filed on Jun. 26, 2015.

(30) Foreign Application Priority Data
Jul. 4, 2014 (JP) 2014-138801

(51) Int. Cl. H01L 29/778; H01L 29/47; H01L 29/10; H01L 29/40; H01L 29/20; H01L 29/205

(52) U.S. Cl. CPC H01L 29/7787; H01L 29/2003; H01L 29/205; H01L 29/1095; H01L 29/402; H01L 29/475

(57) ABSTRACT

A semiconductor device includes: a substrate; a semiconductor stack including a first nitride semiconductor layer and a second nitride semiconductor layer formed above the substrate; a source electrode and a drain electrode formed above a lower surface of the semiconductor stack; a gate electrode; in plan view, a current-drift area; a non-current-drift area; and a collapse reducing electrode formed on the non-current-drift area in the second nitride semiconductor layer, the collapse reducing electrode being formed to have a substantially same potential as the gate electrode. In the semiconductor device, the collapse reducing electrode and the second nitride semiconductor layer have a junction surface functioning as an energy barrier having a rectifying effect in a forward direction from the collapse reducing electrode to the second nitride semiconductor layer.

### CROSS REFERENCE TO RELATED APPLICATIONS

This application is a U.S. continuation application of PCT International Patent Application Number PCT/JP2015/003224 filed on Jun. 26, 2015, claiming the benefit of priority of Japanese Patent Application Number 2014-138801 filed on Jul. 4, 2014, the entire contents of which are hereby incorporated by reference.

### BACKGROUND

1. Technical Field

The present disclosure relates to a semiconductor device, and particularly to a nitride semiconductor device for use in an inverter, an electric power circuit, etc.

2. Description of the Related Art

What is called a nitride semiconductor made of a group III-V nitride compound represented by nitride gallium (GaN) has been drawing attention. The nitride semiconductor is a compound semiconductor expressed by a general expression of InₓGa_{y}Al_{1-x-y}N (0≦x≦1, 0≦y≦1, x+y≦1), and made of aluminum (Al), gallium (Ga), and indium (In) which are Group III elements, and nitride (N) which is a Group V element.

The nitride semiconductor can form various kinds of mixed crystals, and can easily form a heterojunction interface. The heterojunction of the nitride semiconductor is characterized in that a two-dimensional electron gas layer (2DEG layer) having a high concentration occurs at a heterojunction surface due to spontaneous polarization or Piezoelectric polarization even in an undoped state. A field effect transistor (FET) having such a high-concentration 2DEG layer has been drawing attention as a device for high frequency and large electric power.

However, such a FET formed using a nitride semiconductor has several problems. One of the problems is a phenomenon called a current collapse. The current collapse is a phenomenon in which drain current is difficult to flow for a certain period of time when a device is turned off once and then is turned on again. A poor current collapse property hampers fast switching, which causes an extremely serious problem in operations by the device.

As a method for reducing current collapses, it has been considered to reduce an electric field which occurs inside the device when a high voltage is applied to the device. For example, there is a method for reducing an electric field at the end part of a gate by forming a gate field plate in the FET (See Patent Literature 1: Japanese Unexamined Patent Application Publication No. 2004-200248). In addition, Patent Literature 1 discloses that it is good to form a SiN protective film as the uppermost layer in a nitride semiconductor layer, in addition to reduction in the electric field. This is for reducing defect in the interface between the protective film and the nitride semiconductor layer including the SiN film, so as to reduce electrons to be trapped in the defect due to the strong electric field.

As another problem of the FET formed using a nitride semiconductor is gate parasitic capacitance. A large gate parasitic capacitance also hampers fast switching. As a method for reducing the gate parasitic capacitance, there is a method for forming a high resistance layer immediately below the gate resistor (See Patent Literature 1: PCT International Publication No. WO2014-041731).

### SUMMARY

However, conventional techniques are not always sufficient to reduce collapse phenomena and reduce gate parasitic capacitances.

In view of this, the present disclosure was provided to solve the above problems by reducing current collapses and gate parasitic capacitances of a semiconductor device formed using a nitride semiconductor.

In order to solve the above problems, an aspect of the present disclosure is a semiconductor device, including: a substrate; a semiconductor stack including: a first nitride semiconductor layer formed above the substrate; and a second nitride semiconductor layer formed on the first nitride semiconductor layer and having a band gap larger than a band gap of the first nitride semiconductor layer; a source electrode and a drain electrode formed apart from each other above a lower surface of the semiconductor stack; a gate electrode formed between and apart from the source electrode and the drain electrode on the second nitride semiconductor layer, in plan view, a current-drift area which is a substantial current path from the drain electrode to the source electrode in the semiconductor stack when a voltage larger than or equal to a threshold voltage is applied to between the gate electrode and the source electrode; a non-current-drift area which is not a substantial current path from the drain electrode to the source electrode in the semiconductor stack; and a collapse reducing electrode formed discontinuously from the gate electrode on the non-current-drift area in the second nitride semiconductor layer, the collapse reducing electrode being formed to have a substantially same potential as the gate electrode, wherein the collapse reducing electrode and the second nitride semiconductor layer have a junction surface functioning as an energy barrier having a rectifying effect in a forward direction from the collapse reducing electrode to the second nitride semiconductor layer.

With the collapse reducing electrode included in the configuration, it is possible to cause captured electrons to be absorbed or to be re-coupled with holes injected from the electrode part. Thus, the semiconductor device according to the present disclosure can have a reduced number of electrons to be trapped at the end part of the gate electrode and a reduced electric field at the end part of the gate electrode, compared with the semiconductor device without a collapse reducing electrode. Therefore, the semiconductor device according to the present disclosure can prevent occurrence of current collapses.

Furthermore, it is possible to reduce the electrode area by forming the collapse reducing electrode having the same potential as the gate electrode in the non-current-drift area, compared with a configuration in which a collapse reducing electrode is formed to extend to the inside of a current-drift area.

In the semiconductor device according to the aspect of the present disclosure, the collapse reducing electrode may be formed apart from the drain electrode by a minimum distance for obtaining a desired drain voltage resistance.

With this configuration, it is possible to reduce collapses and secure the desired drain voltage resistance.

In the semiconductor device according to the aspect of the present disclosure, the collapse reducing electrode may be formed within the non-current-drift area, between an extension line toward a longitudinal direction of the gate electrode and an extension line toward a longitudinal direction of the drain electrode.

With this configuration, by forming the collapse reducing electrode having smaller dimensions, it is possible to reduce a gate parasitic capacitance.

In the semiconductor device according to the aspect of the present disclosure, the semiconductor stack may have, in plan view, parts which contain active two-dimensional electron gas, the parts being the current-drift area, a part immediately below an entirety of the collapse reducing electrode, and the non-current-drift area between the collapse reducing electrode and the current-drift area.

With this configuration, the area from the area immediately below the collapse reducing electrode to the current-drift area is a low resistance area. Thus, the function of causing captured electrons to be absorbed by the collapse reducing electrode, or the function of injecting holes from the collapse reducing electrode to cause electrons to be re-coupled with the holes are exerted more effectively than in a case in which a high resistance area is formed in one of the immediately-below area and the current-drift area.

In the semiconductor device according to the aspect of the present disclosure, the gate electrode and the collapse reducing electrode may mainly include different materials.

With this configuration, it is possible to increase options for device fabrication methods, and further enhance device properties.

In the semiconductor device according to the aspect of the present disclosure, the collapse reducing electrode may be a nitride semiconductor layer.

With this configuration, it is possible to form an energy barrier at the junction surface between the collapse reducing electrode and the second nitride semiconductor layer.

In the semiconductor device according to the aspect of the present disclosure, the collapse reducing electrode may be an organic semiconductor film.

With this configuration, it is possible to increase options for device fabrication methods.

In the semiconductor device according to the aspect of the present disclosure, the collapse reducing electrode may be an oxide semiconductor layer.

With this configuration, it is possible to increase options for device fabrication methods.

In the semiconductor device according to the aspect of the present disclosure, the collapse reducing electrode may be of a p-conductivity type.

With this configuration, it is possible to inject holes from the collapse reducing electrode to the semiconductor stack part below the collapse reducing electrode. By doing so, it is possible to cause the holes to re-couple with the electrons captured at a trap, and to thereby reduce current collapses more significantly than in a case in which holes are not injected.

In the semiconductor device according to the aspect of the present disclosure, the collapse reducing electrode may be in Schottky contact with the second nitride semiconductor layer.

In this way, the electrons captured at the trap between the end part of the gate and the collapse reducing electrode are absorbed by current that flows from the collapse reducing electrode. In this way, it is possible to reduce the electric field at the end part of the gate, and to reduce current collapses.

An aspect of the present disclosure is a semiconductor device, including: a substrate; a semiconductor stack including: a first nitride semiconductor layer formed above the substrate; and a second nitride semiconductor layer formed on the first nitride semiconductor layer and having a band gap larger than a band gap of the first nitride semiconductor layer; a source electrode and a drain electrode formed apart from each other above a lower surface of the semiconductor stack; a gate electrode formed between and apart from the source electrode and the drain electrode on the second nitride semiconductor layer, in plan view, a current-drift area which is a substantial current path from the drain electrode to the source electrode in the semiconductor stack when a voltage larger than or equal to a threshold voltage is applied to between the gate electrode and the source electrode; a non-current-drift area which is not a substantial current path from the drain electrode to the source electrode in the semiconductor stack; and a collapse reducing electrode formed on the non-current-drift area in the second nitride semiconductor layer, the collapse reducing electrode being formed to have a substantially same potential as the gate electrode, wherein the collapse reducing electrode and the second nitride semiconductor layer have a junction surface functioning as an energy barrier having a rectifying effect in a forward direction from the collapse reducing electrode to the second nitride semiconductor layer, and in plan view, the non-current-drift area in the semiconductor stack includes a high resistance area and a low resistance area, the low resistance area being enclosed by the high resistance area and being in contact with the current-drift area located between the drain electrode and the gate electrode and with the collapse reducing electrode.

With this configuration, the collapse reducing electrode is protected by the high resistance layer against the drain field, it is possible to increase the voltage resistance and the reliability of the device.

In the semiconductor device according to the aspect of the present disclosure, the high resistance area in the semiconductor stack may contain inactive two-dimensional electron gas, and the low resistance area in the semiconductor stack may contain active two-dimensional electron gas.

With this configuration, the collapse reducing electrode is in contact with the two-dimensional electron gas. Thus, it is possible to increase a collapse reducing effect compared with an opposite case.

In the semiconductor device according to the aspect of the present disclosure, the collapse reducing electrode and the gate electrode may mainly include a same material.

In this configuration, the collapse reducing electrode and the gate electrode can be formed at the same time, and thus it is possible to simplify the device fabrication processes.

According to the present disclosure, it is possible to configure a nitride semiconductor transistor which reduce current collapses and have a reduced gate parasitic capacitance, and thus to achieve a semiconductor device which mainly includes a nitride semiconductor material and is applicable to a power transistor.

### BRIEF DESCRIPTION OF DRAWINGS

These and other objects, advantages and features of the disclosure will become apparent from the following description thereof taken in conjunction with the accompanying drawings that illustrate a specific embodiment of the present disclosure.

FIG. 1 is a plan view of a semiconductor device according to Embodiment 1;

FIG. 2 is a section view of the semiconductor device according to Embodiment 1 along A-B line;

FIG. 3 is a section view of the semiconductor device according to Embodiment 1 along C-D line;

FIG. 4 is a plan view of a semiconductor device according to Embodiment 2;

FIG. 5 is a plan view of a semiconductor device according to Embodiment 3;

FIG. 6 is a plan view of a semiconductor device according to Embodiment 4;

FIG. 7 is a plan view of a semiconductor device according to Embodiment 5;

FIG. 8 is a plan view of a semiconductor device according to Embodiment 6;

FIG. 9 is a plan view of a semiconductor device according to Embodiment 7;

FIG. 10 is a plan view of a semiconductor device according to Embodiment 8;

FIG. 11 is a section view of the semiconductor device according to Embodiment 8 along A-B line;

FIG. 12 is a section view of the semiconductor device according to Embodiment 8 along G-H line;

FIG. 13 is a section view of the semiconductor device according to Embodiment 8 along I-J line;

FIG. 14 is a plan view of a semiconductor device according to Embodiment 9;

FIG. 15 is a section view of the semiconductor device according to Embodiment 9 along A-B line;

FIG. 16 is a section view of the semiconductor device according to Embodiment 9 along K-L line; and

FIG. 17 is a section view of the semiconductor device according to Embodiment 9 along M-N line.

### DETAILED DESCRIPTION OF THE EMBODIMENTS

Hereinafter, embodiments according to the present disclosure are described with reference to the drawings.

### Underlying Knowledge Forming Basis of the Present Disclosure

The inventors found that the semiconductor devices disclosed in the BACKGROUND section have the following problems regarding current collapses and gate parasitic capacitances.

First, it is difficult to sufficiently reduce collapse phenomena using the conventional techniques.

This is because it is impossible to sufficiently reduce the electric field at the end part of a gate using only a gate field plate.

In addition, in the case of a switching element of a power device, when a high voltage of approximately several hundred volts is applied, a SiN protective film cannot sufficiently reduce a nitrogen defect at the interface between the SiN protective film and a nitride semiconductor layer. Thus, it is impossible to sufficiently reduce collapse phenomena.

As a result, when the FET transitions from an OFF state to an ON state, an ON resistance in the period starting immediately after the transition and lasting until several μ seconds is increased by several times with respect to a value in an initial state.

In addition, it is difficult to sufficiently reduce the gate parasitic capacitances using the conventional techniques.

This is because each conventional technique increases the area of the gate part to reduce source leak current, which makes it impossible to sufficiently reduce gate parasitic capacitances.

In view of this, the present disclosure was provided to solve the above problem by reducing current collapses and gate parasitic capacitances of a semiconductor device formed using a nitride semiconductor.

### Embodiment 1

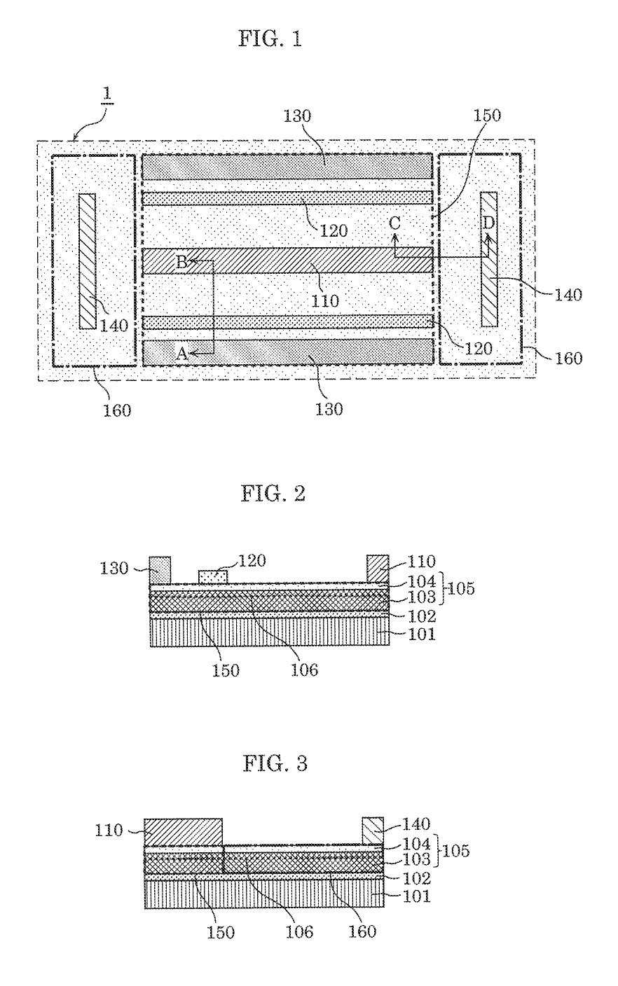

FIG. 1 is a plan view of semiconductor device 1 according to Embodiment 1. In addition, FIG. 2 is a section view of semiconductor device 1 along A-B line in FIG. 1, and FIG. 3 is a section view of semiconductor device 1 along C-D line in FIG. 1. It is to be noted here that semiconductor device 1 is a field effect transistor (FET).

The configuration of semiconductor device 1 is described with reference to FIGS. 1 to 3.

First, semiconductor device 1 includes semiconductor stack 105 having a principal plane direction of (111) and including first nitride semiconductor layer 103 and second semiconductor layer 104 formed above silicon substrate 101 having a thickness of 350 μm via buffer layer 102. Second nitride layer 104 has a band gap larger than the band gap of first nitride semiconductor layer 103. On semiconductor stack 105, source electrode 130 and drain electrode 110 are formed apart from each other. Furthermore, gate electrode 120 is formed on second nitride semiconductor layer 104 apart from source electrode 130 and drain electrode 110.

Here, an area which is a substantial current path from drain electrode 110 to source electrode 130 in semiconductor stack 105 when a voltage larger than or equal to a gate threshold voltage is applied to between gate electrode 120 and source electrode 130 is assumed to be current-drift area 150. Current-drift area 150 is illustrated as an area enclosed by a broken line in each of FIG. 1 which is a plan view and FIGS. 2 and 3 which are section views.

In addition, an area which is not a substantial current path from drain electrode 110 to source electrode 130 in semiconductor stack 105 is assumed to be non-current-drift area 160. Each of non-current-drift areas 160 are illustrated as areas enclosed by an alternate long and short dash line in FIG. 1 which is the plan view, and FIGS. 2 and 3 which are the section views.

Furthermore, collapse reducing electrode 140 having the same potential as gate electrode 120 is formed on non-current-drift area 160 of nitride semiconductor layer 104. In addition, a junction surface of collapse reducing electrode 140 and second nitride semiconductor layer 104 has an energy barrier having a rectifying effect in a forward direction from collapse reducing electrode 140 to second nitride semiconductor layer 104.

The configuration of the semiconductor device is described in further detail.

Semiconductor stack 105 is formed using, for example, metal organic vapor phase epitaxy (MOVPE), so that a semiconductor layer in semiconductor stack 105 has a principal plane direction of (0001).

Buffer layer 102 is formed to have a multi-layer structure including an AlN layer and an AlGaN layer having an Al content of 20% on silicon substrate 101. Buffer layer 102 has a total thickness of approximately 2.1 μm.

First nitride semiconductor layer 103 is a channel layer in which electrons run, and which mainly includes undoped GaN and has a layer thickness of 1.6 μm. It is to be noted that “undoped” means that no impurity is intentionally introduced.

Second nitride semiconductor layer 104 is an electron supply layer, which mainly includes undoped Al_{0.17}Ga_{0.83} and has a layer thickness of 60 nm.

Two-dimensional electron gas layer (abbreviated as 2DEG) is formed at the interface between first nitride semiconductor layer 103 and second nitride semiconductor layer 104.

Each of source electrode 130 and drain electrode 110 has a configuration (what is called a Ti/Al configuration) in which a titanium layer having a thickness of 20 nm is formed above second nitride semiconductor layer 104, and an aluminum layer having a thickness of 200 nm is formed on the titanium layer. It is to be noted that each of source electrode 130 and drain electrode 110 is in ohmic contact with second nitride semiconductor 104. Each of source electrode 130 and drain electrode 110 does not always need to have the Ti/Al configuration, and may be a stack which mainly includes, for example, metal such as Ti, Al, Mo, Hf, etc. or a combination of two or more of them as long as it is in ohmic contact with second nitride semiconductor layer 104.

Gate electrode 120 has a configuration (what is called a Ni/Au configuration) in which a nickel layer having a thickness of 100 nm is formed above second nitride semiconductor layer 104, and a metal layer having a thickness of 200 nm is formed on the nickel layer. Gate electrode 120 is in Schottky contact with second nitride semiconductor layer 104. Gate electrode 120 does not always need to have the Ni/Au configuration, and may be a stack which mainly includes, for example, metal such as Ti, Al, Ni, Pt, Pd, Au, Mo, Hf, etc. or a combination of two or more of them as long as it is in Schottky contact with second nitride semiconductor layer 104.

Collapse reducing electrode 140 is formed as a p-type nitride semiconductor layer which mainly includes a material different from a material of gate electrode 120. Specifically, this p-type nitride semiconductor layer mainly includes Mg-doped p-type GaN having an impurity concentration of 1×10²⁰ cm⁻³ to have a thickness of 200 nm. At this time, the junction surface of collapse reducing electrode 140 and second nitride semiconductor layer 104 has an energy barrier having a rectifying effect in a forward direction from collapse reducing electrode 140 to second nitride semiconductor layer 104.

It is to be noted that collapse reducing electrode 140 which is a p-type nitride semiconductor layer is not limited to GaN, and may be either AlₓGa₁₋ₓN (0<x≦1) or In_{y}Al_{z}Ga_{1-y-z}N (0≦y≦1, 0≦z≦1). In addition, the impurity concentration of Mg may be approximately 1×10¹⁸ cm⁻³ to 1×10²¹ cm⁻³. The width of collapse reducing electrode 140 may be approximately 1 μm to 3 μm although it varies depending on the interval between drain electrode 110 and gate electrode 120.

Collapse reducing electrode 140 is formed to be apart from drain electrode 110 by a minimum distance (6 μm) for obtaining a desired drain voltage resistance (for example, 600 V).

In addition, in the layout of this FET in the plan view of FIG. 1, semiconductor stack 105 is divided into current-drift area 150 which corresponds to a substantial current path and non-current-drift areas 160 which do not correspond to substantial current paths. Current-drift area 150 is an area which dominantly determines mainly an ON resistance and a voltage resistance of the element. In addition, each non-current-drift area 160 means that it is an area which does not dominantly determine an ON resistance and a voltage resistance of the element.

Current-drift area 150 in semiconductor stack 105 is a low resistance area in which two-dimensional electron gas layer 106 is active. A semiconductor stack 105 part immediately below collapse reducing electrode 140 is also a low resistance area in which two-dimensional electron gas layer 106 is active. Likewise, non-current-drift area 160a which is in semiconductor stack 105 and located between collapse reducing electrode 140 and current-drift area 150 is also a low resistance area in which two-dimensional electron gas layer 106 is active.

It is to be noted that each of gate electrode 120, source electrode 130, and drain electrode 110 has a finger configuration, and the length (the length in the direction parallel to the horizontal direction of the paper sheet in FIG. 1) of a finger in each of the electrodes ranges from 10 μm to 500 μm. In addition, the width (the width in the perpendicular direction of the paper sheet in FIG. 1) of the electrode of source electrode 130 is 7 μm, and the width of the electrode of drain electrode 110 is 7 μm. In addition, the width (what is called a gate length) of the electrode of gate electrode 120 is 1 μm, and the width of the electrode of collapse reducing electrode 140 is 2 μm.

The interval between source electrode 130 and drain electrode 110 (the interval between closer ends of opposite ones of the electrodes) is 8.5 μm. Gate electrode 120 is disposed at a position of 1.5 μm from a closer end of source electrode 130, and drain electrode 110 is disposed at a position of 6 μm from a closer end of gate electrode 120.

Next, operations performed by field effect transistor illustrated in FIG. 1 are described.

The field effect transistor operates as indicated below for example. A positive bias (hereinafter referred to as a drain voltage) is applied to between drain electrode 110 and source electrode 130, and a positive voltage is applied to gate electrode 120. In this way, it is possible to cause current (hereinafter referred to as drain current) to flow from drain electrode 110 to source electrode 130.

In current-drift area 150, drain current flows from drain electrode 110 to source electrode 130 via a channel which mainly includes two-dimensional electron gas layer 106 formed in the proximity of the interface between first nitride semiconductor layer 103 and second nitride semiconductor layer 104.

On the other hand, the voltage of gate electrode 120 is set to a gate threshold voltage of the FET or below. For example, gate electrode 120 is caused to be short-circuited from source electrode 130. This stops flow of drain current.

In this way, a switching operation of causing and stopping flow of drain current to the FET is performed by turning ON and OFF an application voltage of gate electrode 120.

The switching operation is performed by making an inductor load (hereinafter referred to as load L) contact with the drain terminal. At the moment of turning ON or turning OFF, a drain voltage transiently rises, for example, from several tens voltages to several hundreds voltages in a state in which the voltage higher than or equal to the gate threshold voltage is being applied to gate electrode 120. When the drain voltage increases in this way under a gate bias condition that the drain current flows, electron current flows in a strong electric field area in the proximity of gate electrode 120. This strong electric field causes electrons to be captured in a defect or on the interface of a surface layer in second nitride semiconductor layer 104.

It is to be noted that the value of load L varies, for example, in a range from 10 pH to 5 mH, depending on output of the semiconductor device or an input voltage.

In addition, the switching operation is performed, for example, at a frequency approximately ranging from 20 kHz for an inverter to 200 kHz for power factor correction circuit (PFC) and further to 500 kHz for an LLC resonant converter. A drain voltage to be applied is, for example, direct current (DC) approximately ranging from 140 V to 400 V. The gate voltage is applied, for example, between 0 V (OFF time) and 3.5 V (ON time). However, there is an application method in which a spike voltage is generated at the moment of turning ON or OFF.

In the case of a conventional FET, a channel scatters when a switching operation is continued while electrons having negative charge are being captured, which decreases electron mobility and increases an ON resistance. Furthermore, what is called a current collapse occurs. The current collapse is a breakdown caused when the captured electrons cause a field concentration at the end part of the gate.

In contrast, in the case of the FET of the present disclosure, by forming collapse reducing electrode 140 including the p-type nitride semiconductor layer and having the same potential as gate electrode 120 and injecting holes from collapse reducing electrode 140 while a positive bias is being applied to gate electrode 120, it is possible to cause the captured electrons to be re-coupled with the holes.

More specifically, when a voltage, which is for example 3 V or more, higher than or equal to an energy barrier formed with the p-type nitride semiconductor layer and the second nitride semiconductor layer is applied to gate electrode 120, the same potential is applied to collapse reducing electrode 140 formed using the p-type nitride semiconductor layer, and current flows from collapse reducing electrode 140 to source electrode 130. At this time, holes are injected and re-couple with the captured electrons, which produces a collapse reducing effect.

The writers of the present disclosure tested this effect, and found that an ON resistance did not increase even when a voltage of 600 V was applied.

The above descriptions have been given taking an example in which collapse reducing electrode 140 is of a p-conductivity type. Collapse reducing electrode 140, however, may be of n-conductivity type. In the case of n-type collapse reducing electrode 140, captured electrons are absorbed by collapse reducing electrode 140, which produces a collapse reducing effect.

In this semiconductor device, gate electrode 120 and collapse reducing electrode 140 having the same potential as gate electrode 120 are formed in non-current-drift area 160. With this configuration, it is possible to reduce the electrode area compared with the configuration in which a collapse reducing electrode extends into current-drift area 150, and thus to reduce gate parasitic capacitance.

Since collapse reducing electrode 140 is formed to be apart from drain electrode 110 by a minimum distance (6 μm) for obtaining a desired drain voltage resistance (for example, 600 V), it is possible to reduce collapses and secure a desired drain voltage resistance.

Current-drift area 150 in semiconductor stack 105 is the low resistance area in which two-dimensional electron gas layer 106 is active, the semiconductor stack 105 part immediately below collapse reducing electrode 140 is also the low resistance area in which two-dimensional electron gas layer 106 is active, and non-current-drift area 160 which is in the semiconductor stack 105 and located between collapse reducing electrode 140 and current-drift area 150 is also the low resistance area in which two-dimensional electron gas layer 106 is active. For this reason, compared with the case in which a high resistance area is formed in any of the parts, the function of injecting holes from collapse reducing electrode 140 so as to cause electrons to be re-coupled with the holes is exerted more effectively (the high resistance area here is an area having a resistance value higher than or equal to a measurement limit value in normal resistance measurement, or exhibiting a semi-insulating property or an insulating property).

In the semiconductor device, collapse reducing electrode 140 mainly includes the material different from the material of gate electrode 120. Collapse reducing electrode 140 is formed using a p-type GaN layer while gate electrode 120 is formed to have a Ni/Au configuration. By configuring the gate electrode and the collapse reducing electrode using different materials, it is possible to increase options for device fabrication methods and further enhance the properties of the semiconductor device.

More specifically, for example, the semiconductor device having gate electrode 120 formed using the Ni/Au configuration can provide a reduced gate resistance compared with, for example, a semiconductor device in which each of a gate electrode and a collapse reducing electrode includes a p-type GaN layer. As a result, the semiconductor device can have a smaller gate wiring area compared with a semiconductor device including gate electrode 120 having a p-type GaN layer, and thus can provide a reduced gate parasitic capacitance. As a result, it is possible to cause the semiconductor device to perform fast switching.

In addition, since no p-type GaN layer is used for the gate electrode, for example, when second nitride semiconductor layer 104 is formed thickly to have a thickness of 80 nm or more, it is possible to form collapse reducing electrode 140 including second nitride semiconductor layer 104 and a p-type GaN layer through one-time continuous epitaxial growth. In short, it is possible to simplify the device fabrication processes.

On the other hand, when a p-type GaN layer is used for a gate electrode, in order to thickly form second nitride semiconductor layer 104 to have a thickness of 80 nm or more, a gate recess forming process needs to be performed between epitaxial growth for the second nitride semiconductor layer and epitaxial growth for a p-type GaN layer. In other words, since the two epitaxial growth processes and the gate recess forming process are required, this configuration produces the disadvantage that complicated processes are required.

In this way, by configuring a gate electrode and a collapse reducing electrode using different materials, specifically, Ni/Au for the gate electrode and p-type GaN for the collapse reducing electrode, it is possible to increase the options for device fabrication methods and enhance the properties of the semiconductor device more significantly compared with a semiconductor device in which each of a gate electrode and a collapse reducing electrode is formed as a p-type GaN layer.

### Embodiment 2

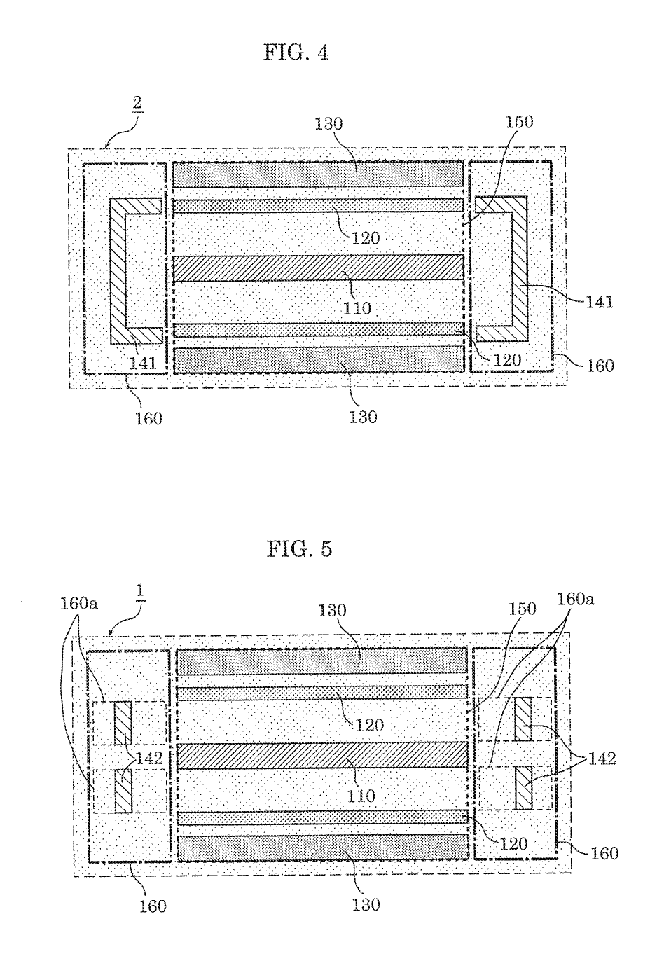

FIG. 4 is a plan view of semiconductor device 2 according to Embodiment 2. Semiconductor device 2 here is an FET.

Semiconductor device 2 includes collapse reducing electrode 141 whose shape is different in plan view from the one in the FET illustrated in FIG. 1. In other words, collapse reducing electrode 141 is formed apart from drain electrode 110 by a minimum distance (6 μm) for obtaining a desired drain voltage resistance (for example, 600 V) and in the proximity of gate electrode 120 in current-drift area 150. The remaining configuration of the FET including the electrodes each having the finger structure here is the same as that of the FET illustrated in Embodiment 1 (See FIGS. 1 to 3).

By forming collapse reducing electrode 141 as illustrated in FIG. 4 and injecting holes therethrough, it is possible to inject a larger number of holes than in Embodiment 1 into the end part of gate electrode 120 so as to cause captured electrons to be re-coupled with the holes. Therefore, it is possible to produce a larger collapse reduction effect.

### Embodiment 3

FIG. 5 is a plan view of semiconductor device 3 according to Embodiment 3. Semiconductor device 3 here is an FET.

Semiconductor device 3 includes collapse reducing electrode 142 whose shape is different in plan view from the one in the FET illustrated in FIG. 1.

In other words, collapse reducing electrode 142 is formed within non-current-drift area 160a of non-current-drift area 160. Non-current-drift area 160a is located between an extension line in the longitudinal direction of gate electrode 120 and an extension line in the longitudinal direction of drain electrode 110. The remaining configuration of the FET including the electrodes each having the finger structure here is the same as that of the FET illustrated in Embodiment 1 (See FIGS. 1 to 3).

A collapse is caused by electrons captured mainly in current-drift area 150 between gate electrode 120 and drain electrode 110. The electrons are re-coupled with the holes injected through collapse reducing electrode 142. At this time, as illustrated in FIG. 5, collapse reducing electrode 142 may be formed within non-current-drift area 160a located between the extension line in the longitudinal direction of gate electrode 120 and the extension line in the longitudinal direction of drain electrode 110. By forming optimum collapse reducing electrode 142 having a reduced area, it is possible to reduce a parasitic capacitance that corresponds to the areas of collapse reducing electrode 142 and gate electrode 120.

### Embodiment 4

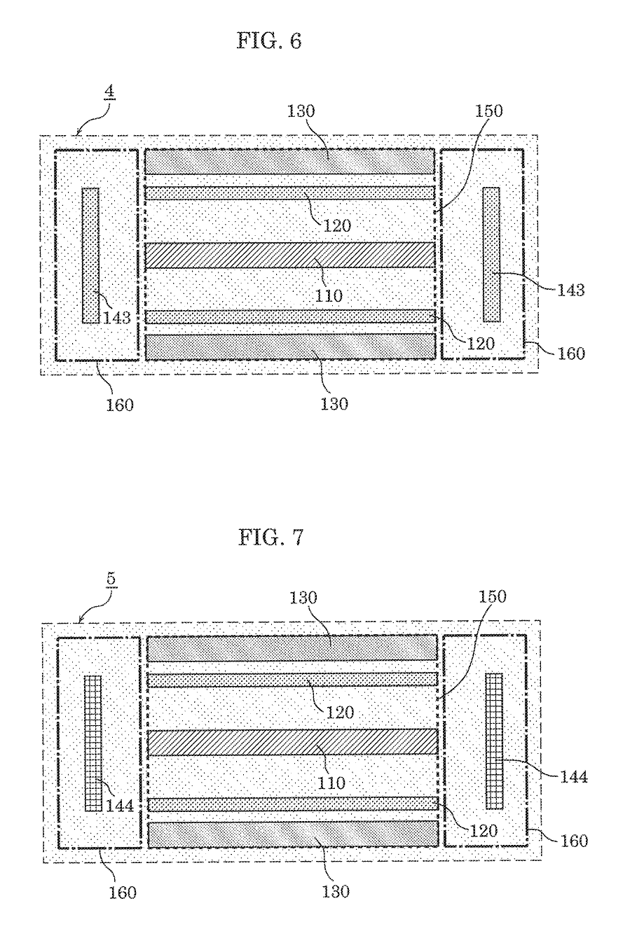

FIG. 6 is a plan view of semiconductor device 4 according to Embodiment 4. Semiconductor device 4 here is an FET.

Semiconductor device 4 is different from the FET illustrated in FIG. 1 in the points of: including collapse reducing electrode 143 which mainly includes a same material as gate electrode 120; and having a configuration (what is called a Ni/Ai configuration) in which a nickel layer having a thickness of 100 nm is formed above second nitride semiconductor layer 104, and a metal layer having a thickness of 200 nm is formed on the nickel layer. Collapse reducing electrode 143 is in Schottky contact in which a rectifying effect in the forward direction to second nitride semiconductor layer 104 is exhibited. The remaining configuration of the FET including the electrodes each having the finger structure here is the same as that of the FET illustrated in Embodiment 1 (See FIGS. 1 to 3).

In this way, collapse reducing electrode 143 may be formed with a Schottky electrode. In this case, the electrons captured at the end part of gate electrode 120 are absorbed by collapse reducing electrode 143. As a result, no current collapse that is a problem of a conventional FET occurs. More specifically, when a voltage, which is for example 3 V or more, higher than or equal to an energy barrier formed with the Schottky electrode and second nitride semiconductor layer 104 is applied to gate electrode 120, the same potential is applied to collapse reducing electrode 143 which is the Schottky electrode, and current flows from collapse reducing electrode 143 to source electrode 130. At this time, electrons captured mainly at the end part of gate electrode 120 can be absorbed by collapse reducing electrode 143. In this way, the FET according to this embodiment is capable of reducing captured electrons, preventing increase in ON resistance, and reducing field concentration, and thereby reducing occurrence of current collapses.

In addition, since collapse reducing electrode 143 and gate electrode 120 mainly include the same material, both of them can be formed in one process. Since the device fabrication processes can be simplified, it is possible to reduce manufacturing cost.

### Embodiment 5

FIG. 7 is a plan view of semiconductor device 5 according to Embodiment 5. Semiconductor device 5 here is an FET.

Semiconductor device 5 is different from the FET illustrated in FIG. 1 in the point of including collapse reducing electrode 144 formed using a p-type organic semiconductor layer, instead of the p-type nitride semiconductor layer. The remaining configuration of the FET including the electrodes each having the finger structure here is the same as that of the FET illustrated in Embodiment 1 (See FIGS. 1 to 3).

By forming collapse reducing electrode 144 using the p-type organic semiconductor layer and injecting holes therethrough, it is possible to cause captured electrons to be re-coupled with the holes.

The organic semiconductor layer includes a pentacene derivative, a tetracene derivative, an anthracene derivative, or the like belonging to acenes, or perylene, rubrene, phthalocyanine, Zn phthalocyanine, or the like. Tetracene or Zn phthalocyanine is preferable. The organic semiconductor layer is preferably formed using an evaporation method, a sputtering method, a spin-on method, or a sol-gel method, or more preferably formed using a resistance heating vapor deposition method or a spin-on method. The organic semiconductor layer is formed to have a thickness of, for example, approximately 10 to 100 nm.

In this way, by forming the collapse reducing electrode using the p-type organic semiconductor layer instead of the p-type nitride semiconductor layer, it is possible to increase the collapse reducing effect and to further simplify the manufacturing processes.

Although the above descriptions have been given taking a case in which the organic semiconductor layer is of a p-conductivity type, the conductivity type does not always need to be p-type.

### Embodiment 6

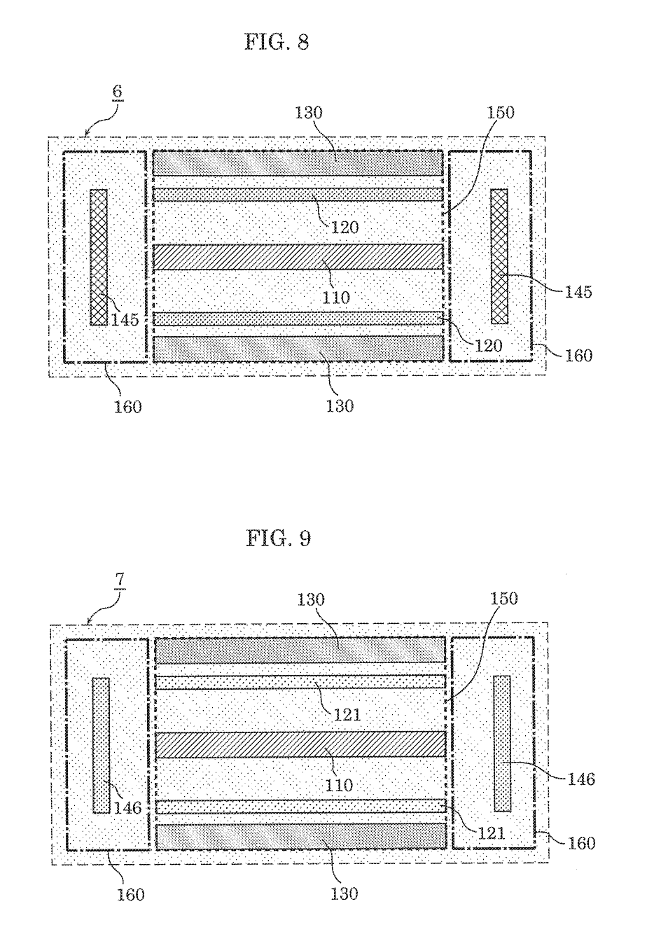

FIG. 8 is a plan view of semiconductor device 6 according to Embodiment 6. Semiconductor device 6 here is an FET.

Semiconductor device 6 is different from the FET illustrated in FIG. 1 in the point of including collapse reducing electrode 145 formed using a p-type oxide semiconductor layer, instead of the p-type nitride semiconductor layer. The remaining configuration of the FET here including the electrodes each having the finger structure is the same as that of the FET illustrated in Embodiment 1 (See FIGS. 1 to 3).

By forming the p-type oxide semiconductor layer and injecting holes therethrough, it is possible to cause captured electrons to be re-coupled with the holes.

The oxide semiconductor layer mainly includes, for example, a nickel oxide (NiO) obtained by oxidizing nickel (Ni) formed using electron-beam evaporation. The organic semiconductor layer is formed to have a thickness of, for example, approximately 10 to 100 nm. The oxide semiconductor layer can be formed using a p-type oxide semiconductor which is a ferric oxide (FeO₂), a cobalt oxide (CoO₂), a manganous oxide (MnO), a copper oxide (CuO), or the like, other than the nickel oxide (NiO).

In this way, by forming the collapse reducing electrode using the p-type oxide semiconductor layer instead of the p-type nitride semiconductor layer, it is possible to increase the collapse reducing effect and to further simplify the manufacturing processes.

Although the above descriptions have been given taking a case in which the oxide semiconductor layer is of a p-conductivity type, the conductivity type does not always need to be p-type.

### Embodiment 7

FIG. 9 is a plan view of semiconductor device 7 according to Embodiment 7. Semiconductor device 7 here is an FET.

Semiconductor device 7 is different from the FET illustrated in FIG. 1 in the points of: including gate electrode 121 formed using a p-type nitride semiconductor layer, instead of Ni/Au; including collapse reducing electrode 146 formed using a material different from a material of gate electrode 121; and having a configuration (what is called a Ni/Au configuration) in which a nickel layer having a thickness of 100 nm is formed above second nitride semiconductor layer 104, and a metal layer having a thickness of 200 nm is formed on the nickel layer. The remaining configuration of the FET including the electrodes each having the finger structure here is the same as that of the FET illustrated in Embodiment 1 (See FIGS. 1 to 3).

In this way, the gate electrode may be formed using a p-type nitride semiconductor layer. In this case, it is possible to further reduce gate leak current and source leak current, and thereby increasing the reliability of the element, compared with gate electrode 120 having the Ni/Au configuration illustrated in FIG. 1.

In Semiconductor device 7, collapse reducing electrode 146 formed using the material different from the material of gate electrode 121 functions as a Ni/Au Schottky electrode with respect to the p-type nitride semiconductor layer of gate electrode 121. In this way, by configuring the gate electrode and the collapse reducing electrode using different materials, it is possible to increase options for device fabrication methods and further enhance the properties of the semiconductor device.

More specifically, since collapse reducing electrode 146 is formed using the Ni/Au configuration in the semiconductor device including, collapse reducing electrode 146 and second nitride semiconductor layer 104 have a junction functioning as a Schottky junction which is simpler than a semiconductor PN junction in, for example, a semiconductor device including a GaN layer in which gate electrode 121 and collapse reducing electrode 146 are each a p-type nitride semiconductor.

As a result, variation in element properties can be reduced.

### Embodiment 8

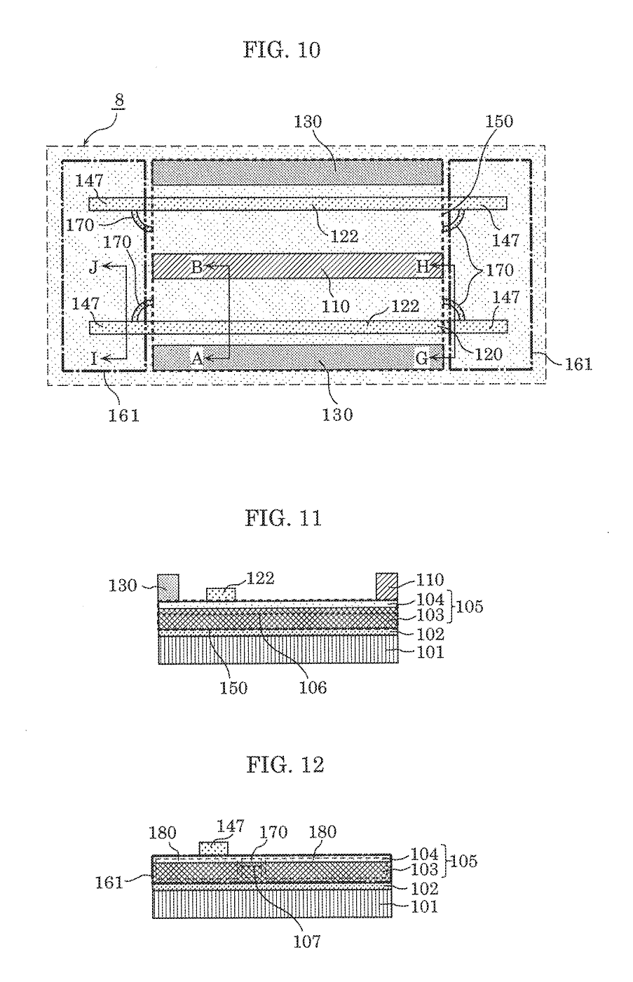

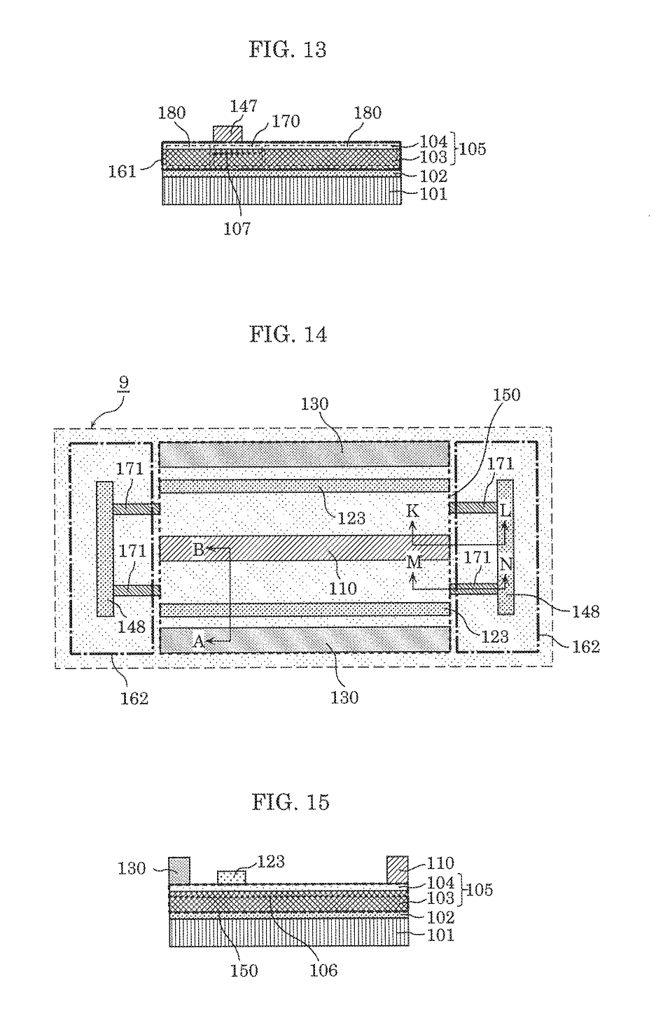

FIG. 10 is a plan view of semiconductor device 8 according to Embodiment 8. In addition, FIG. 11 is a section view of semiconductor device 8 along A-B line in FIG. 10, FIG. 12 is a section view of semiconductor device 8 along G-H line in FIG. 10, and FIG. 13 is a section view of semiconductor device 8 along I-J line in FIG. 10. Semiconductor device 8 here is an FET.

The configuration of semiconductor device 8 is described with reference to FIGS. 10 to 13.

First, the semiconductor device includes semiconductor stack 105 having a principal plane direction of (111) and including first nitride semiconductor layer 103 and second semiconductor layer 104 formed above a silicon substrate 101 having a thickness of 350 μm via buffer layer 102. Second nitride layer 104 has a band gap larger than the band gap of first nitride semiconductor layer 103. On semiconductor stack 105, source electrode 130 and drain electrode 110 are formed apart from each other. Furthermore, gate electrode 122 is formed on second nitride semiconductor layer 104 apart from source electrode 130 and drain electrode 110.

Here, an area which is substantially a current path from drain electrode 110 to source electrode 130 in semiconductor stack 105 when a voltage larger than or equal to a gate threshold voltage is applied to between gate electrode 122 and source electrode 130 is assumed to be current-drift area 150. Current-drift area 150 is illustrated as an area enclosed by a broken line in each of FIG. 10 which is a plan view and FIG. 11 which is a section view.

In addition, an area which is not a substantial current path from drain electrode 110 to source electrode 130 in semiconductor stack 105 is assumed to be a non-current-drift area. Each of non-current-drift areas is illustrated as an area enclosed by an alternate long and short dash line in FIG. 10 which is the plan view, and FIGS. 12 and 13 which are section views.

Furthermore, collapse reducing electrode 147 having the same potential as gate electrode 122 is formed on non-current-drift area 161 of nitride semiconductor layer 104. In addition, collapse reducing electrode 147 and second nitride semiconductor layer 104 have a junction surface functioning as an energy barrier having a rectifying effect in a forward direction from collapse reducing electrode 147 to second nitride semiconductor layer 104.

As illustrated in FIGS. 12 and 13 which are section views, high resistance area 180 and low resistance area 170 enclosed by high resistance area 180 are formed on non-current-drift area 161 of semiconductor stack 105. Low resistance area 170 is in contact with current-drift area 150. In addition, collapse reducing electrode 147 is formed in contact with low resistance area 170 in non-current-drift area 161.

High resistance area 180 of semiconductor stack 105 contains inactive two-dimensional electron gas, and low resistance area 180 of semiconductor stack 105 contains active two-dimensional electron gas.

Collapse reducing electrode 147 and gate electrode 122 are formed using the same material.

The configuration of the semiconductor device is described in further detail.

Semiconductor stack 105 is formed using, for example, metal organic vapor phase epitaxy (MOVPE), so that a semiconductor layer in semiconductor stack 105 has a principal plane direction of (0001).

Buffer layer 102 is formed to have a multi-layer structure including an AlN layer and an AlGaN layer on silicon substrate 101. Buffer layer 102 has a total thickness of approximately 2.1 μm.

First nitride semiconductor layer 103 is a channel layer in which electrons run, is formed using undoped GaN, and has a layer thickness of 1.6 μm. It is to be noted that “undoped” means that no impurity is intentionally introduced.

Second nitride semiconductor layer 104 is an electron supply layer, mainly includes undoped Al_{0.17}Ga_{0.83}, and has a layer thickness of 60 nm.

Two-dimensional electron gas layer 106 (abbreviated as 2DEG) is formed at the interface between first nitride semiconductor layer 103 and second nitride semiconductor layer 104.

Each of source electrode 130 and drain electrode 110 has a configuration (what is called a Ti/Al configuration) in which a titanium layer having a thickness of 20 nm is formed above second nitride semiconductor layer 104, and an aluminum layer having a thickness of 200 nm is formed on the titanium layer. It is to be noted that each of source electrode 130 and drain electrode 110 is in ohmic contact with second nitride semiconductor 104. Each of source electrode 130 and drain electrode 110 does not always need to have the Ti/Al configuration, and may be a stack which mainly includes, for example, metal such as Ti, Al, Mo, Hf, etc. or a combination of two or more of them as long as it is in ohmic contact with second nitride semiconductor 104.

Gate electrode 122 is formed using a p-type nitride semiconductor. Specifically, this p-type nitride semiconductor layer which mainly includes Mg-doped p-type GaN having an impurity concentration of 1×10²⁰ cm⁻³ to have a layer thickness of 200 nm. Collapse reducing electrode 147 is formed using the same material as gate electrode 122, and is a p-type nitride semiconductor layer which specifically mainly includes Mg-doped p-type GaN having an impurity concentration of 1×10²⁰ cm⁻³. At this time, collapse reducing electrode 147 and second nitride semiconductor layer 104 have a junction surface functioning as an energy barrier having a rectifying effect in a forward direction from collapse reducing electrode 147 to second nitride semiconductor layer 104.

It is to be noted that the p-type nitride semiconductor layer is not limited to GaN, and may be either AlₓGa₁₋ₓN (0<x≦1) or In_{y}Al_{z}Ga_{1-y-z}N (0≦y≦1, 0≦z≦1). In addition, the impurity concentration of Mg may be approximately 1×10¹⁸ cm⁻³ to 1×10²¹ cm⁻³. In addition, the width (what is called a gate length) of each of gate electrode 122 and the width of collapse reducing electrode 147 is 1 μm.

In addition, in the layout of this FET in the plan view of FIG. 10, semiconductor stack 105 is divided into current-drift area 150 which corresponds to a substantial current path and non-current-drift areas 161 which do not correspond to substantial current paths. Current-drift area 150 is an area which dominantly determines mainly an ON resistance and a voltage resistance of the element. In addition, each non-current-drift area 161 means that it is an area which does not dominantly determine an ON resistance and a voltage resistance of the element.

It is to be noted that each of gate electrode 120, source electrode 130, and drain electrode 110 has a finger configuration, and the length (the length in the direction parallel to the horizontal direction of the paper sheet in FIG. 10) of a finger in each of the electrodes ranges from 10 μm to 500 μm. In addition, the width (the width in the perpendicular direction of the paper sheet in FIG. 10) of the electrode of source electrode 130 is 7 μm, and the width of the electrode of drain electrode 110 is 7 μm.

The interval between source electrode 130 and drain electrode 110 (the interval between closer ends of opposite ones of the electrodes) is 8.5 μm. Gate electrode 120 is disposed at a position of 1.5 μm from a closer end of source electrode 130, and drain electrode 110 is disposed at a position of 6 μm from a closer end of gate electrode 120.

High resistance area 180 is formed to extend from second nitride semiconductor layer 104 to the inside of first nitride semiconductor layer 103 in the depth direction (the direction parallel to the substrate). High resistance area here is an area in which a resistance value is higher than or equal to a measurement limit value in normal resistance measurement.

Low resistance area 170 of semiconductor stack 105 is an area in which two-dimensional electron gas layer 107 is active and which has a width of 1 μm in the plan view of FIG. 10. Furthermore, low resistance area 170 is in contact with current-drift area 150 at a position apart from the end part of gate electrode 122 by approximately 1.5 μm. Low resistance area 170 is formed in contact with collapse reducing electrode 147 at a position apart from current-drift area 150 by approximately 1 μm.

Next, operations performed by field effect transistor illustrated in FIG. 8 are described.

The field effect transistor operates as indicated below for example. A positive bias (hereinafter referred to as a drain voltage) is applied to between drain electrode 110 and source electrode 130, and a positive voltage is applied to gate electrode 122. In this way, it is possible to cause current (hereinafter referred to as drain current) to flow from drain electrode 110 to source electrode 130.

Drain current flows from drain electrode 110 to source electrode 130 via a channel which mainly includes two-dimensional electron gas layer 106 formed in the proximity of the interface between first nitride semiconductor layer 103 and second nitride semiconductor layer 104.

On the other hand, the voltage of gate electrode 122 is set to a gate threshold voltage of the FET or below. For example, gate electrode 120 is caused to be short-circuited from source electrode 130. This stops flow of drain current.

In this way, a switching operation of causing and stopping flow of drain current to the FET is performed by switching ON and OFF an application voltage of gate electrode 122.

The switching operation is performed by making an inductor load (hereinafter referred to as load L) contact with the drain terminal of the FET. At the moment of turning ON or turning OFF, a drain voltage transiently rises, for example, from several tens voltages to several hundreds voltages in a state in which the voltage higher than or equal to the gate threshold voltage is being applied to gate electrode 122. When the drain voltage increases in this way under a gate bias condition that the drain current flows, electron current flows in a strong electric field area in the proximity of gate electrode 122. This strong electric field causes electrons to be captured in a defect or in the interface of a surface layer in second nitride semiconductor layer 104.

In the case of a conventional FET, a channel scatters when a switching operation is continued while electrons having negative charge are being captured, which decreases electron mobility and increases an ON resistance. Furthermore, what is called a current collapse occurs. The current collapse is a breakdown caused when the captured electrons causes a field concentration at the end part of the gate.

In contrast, in the case of the FET of the present disclosure, by forming collapse reducing electrode 147 including the p-type nitride semiconductor layer and having the same potential as gate electrode 122 and injecting holes from collapse reducing electrode 147 via low resistance area 170 while a positive bias is being applied to gate electrode 122, it is possible to cause the captured electrons to be re-coupled with the holes.

More specifically, when a voltage, which is for example 3 V or more, higher than or equal to an energy barrier formed with the p-type nitride semiconductor layer and the second nitride semiconductor layer is applied to gate electrode 122, the same potential is applied to collapse reducing electrode 147 formed using the p-type nitride semiconductor layer, and current flows from the p-type nitride semiconductor layer in collapse reducing electrode 147 to source electrode 130 via low resistance area 170. At this time, holes are injected and re-couple with the captured electrons, which produces a collapse reducing effect.

The writers of the present disclosure tested this effect, and found that an ON resistance did not increase even when a voltage of 600 V is applied.

In this embodiment, collapse reducing electrode 147 is configured to be enclosed and protected by high resistance area 180 against a drain high field. Thus, it is possible to increase the voltage resistance and reliability of the device.

In addition, since collapse reducing electrode 147 is made contact with low resistance area 170 (two-dimensional electron gas layer 107), it is possible to increase the collapse reducing effect compared with the opposite case.

Collapse reducing electrode 147 and gate electrode 122 are formed using the same material (the p-type nitride semiconductor layer). For this reason, a collapse reducing electrode and a gate electrode can be formed at the same time, and thus it is possible to simplify the device fabrication processes.

### Embodiment 9

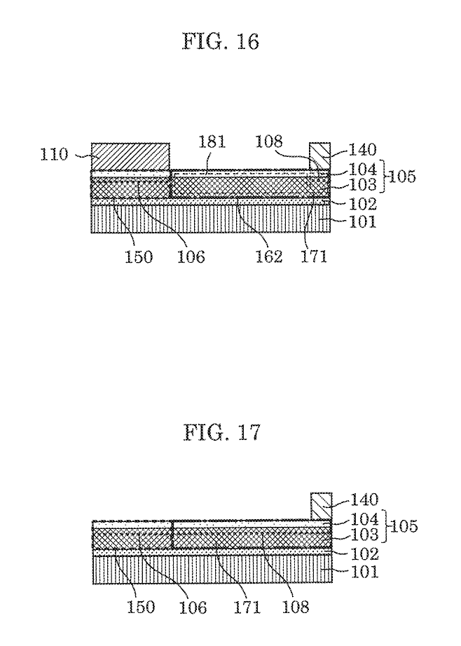

FIG. 14 is a plan view of semiconductor device 9 according to Embodiment 9. In addition, FIG. 15 is a section view of semiconductor device 9 along A-B line in FIG. 14, FIG. 16 is a section view of semiconductor device 9 along K-L line in FIG. 14, and FIG. 17 is a section view of semiconductor device 9 along M-N line in FIG. 14. Semiconductor device 9 here is an FET.

Semiconductor device 9 is different from the FET illustrated in FIG. 10 in the shapes of collapse reducing electrode 148 and low resistance area 171. Non-current-drift area 162 is the same as non-current-drift area 161, two-dimensional electron gas layer 108 is the same as two-dimensional electron gas layer 106, and high resistance area 181 is the same as high resistance area 180.

Even with this configuration, by injecting holes from collapse electrode 148 via low resistance area 171 when a positive bias is applied to gate electrode 123, it is possible to cause captured electrons to be re-coupled with the holes. This is effective to reduce collapses.

The remaining configuration of the FET including the electrodes each having the finger structure here is the same as that of the FET illustrated in Embodiment 8 (See FIGS. 10 to 13).

Examples in which source electrode 130 and drain electrode 110 are formed on semiconductor stack 105 in the above embodiments, but they may be formed above silicon substrate 101 as long as they are in contact with semiconductor stack 105. For example, it is also good to form a via hole passing through silicon substrate 101 and second nitride semiconductor layer 104, form a metal layer above a rear surface of silicon substrate 101 and in the via hole, and thereby cause the metal layer to be in contact with electrodes formed on the surface of second nitride semiconductor layer 104.

Although a Si substrate is used as a substrate in each of the above embodiments, it is also possible to use a sapphire substrate, a SiC substrate, a GaN substrate, a spinel substrate, a GaAs substrate, or the like, instead of the Si substrate. Although the principal plane direction of the Si substrate is the (111) plane above, the principal plane direction of the Si substrate may be a (001) plane. In the case of a hexagonal crystal substrate such as a GaN substrate, the principal plane direction can be the (0001) plane, or may be either a (11-20) plane or a (10-10) plane.

An optimum thickness of buffer layer 102 is selected based on the thicknesses of an AlN layer and AlGaN layer in the multi-layer structure, and an optimum Al content of buffer layer 102 is selected based on the layer structure of the semiconductor device to be formed, a crystal growth condition, a material of the substrate, etc. In the multi-layer structure, the thicknesses of the AlN layer and the AlGaN layer can be made thicker at the substrate side and thinner at the first nitride semiconductor layer 103 side. Alternatively, as for the composition of the AlGaN layer, the Al content can be increased at the substrate side and reduced at the first nitride semiconductor layer 103 side.

Alternatively, a super-lattice buffer layer or a single layer of AlN, AlGaN, or GaN can be used to form buffer layer 102.

Buffer layer 102 has a total thickness of approximately 2.1 μm in each of the above embodiments, the total thickness is not limited to approximately 2.1 μm depending on the configuration of buffer layer 102.

In addition, buffer layer 102, first nitride semiconductor layer 103, and second nitride semiconductor layer 104 may be configured by arbitrarily selecting x and y in AlₓIn_{y}Ga_{1-x-y}N (0≦x≦1, 0≦y≦1) so that the resulting nitride semiconductor can have desired device properties.

In addition, what is called MISFET including an insulating layer in a gate electrode part is also possible. Alternatively, what is called MOSFET including an oxide film as an insulating layer is also possible as a matter of course. As an insulating layer, the following can be used: a silicon nitride (SiN), an aluminum nitride (AlN), a silicon oxide (SiO₂), a silicon oxynitride (SiON), an aluminium oxide (Al₂O₃), an aluminum oxynitride (AlON), and a titanium oxide (TiO₂). Alternatively, it is also possible to use a layer obtainable by selectively causing second nitride semiconductor 104 to be subjected to thermal oxidation.

Alternatively, an FET having a recess gate formed in a gate electrode part is also possible. The FET may be formed as a MISFET or a MOSFET by forming an insulating layer on the bottom of the recess.

Alternatively, it is also good to form a p-type semiconductor layer (of, for example, p-type GaN, p-type AlGaN, p-type NiO, or the like) in the gate electrode part, and provide a junction-type transistor (JFET) having a gate electrode formed on the p-type semiconductor layer.

It is to be noted that the lengths, widths, thicknesses, areas of the electrodes and wiring described in the above embodiments are mere examples, and thus the values thereof may vary depending on the applications, purposes, etc. of the semiconductor devices. In addition, materials of the electrodes and wiring described in the above embodiments are also mere examples, and thus various materials may be used depending on the applications, purposes, etc. of the semiconductor devices.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The semiconductor device according to the present disclosure is a field effect device formed using a nitride semiconductor which reduces current collapses and have a reduced gate parasitic capacitance. The semiconductor device is useful as a power device for use as an inverter, a power circuit, or the like.

What is claimed is:

1. A semiconductor device, comprising:
a substrate;
a semiconductor stack including:
a first nitride semiconductor layer formed above the substrate; and
a second nitride semiconductor layer formed on the first nitride semiconductor layer and having a band gap larger than a band gap of the first nitride semiconductor layer;
a source electrode and a drain electrode formed apart from each other above a lower surface of the semiconductor stack;
a gate electrode formed between and apart from the source electrode and the drain electrode on the second nitride semiconductor layer,
in plan view,
a current-drift area which is a substantial current path from the drain electrode to the source electrode in the semiconductor stack when a voltage larger than or equal to a threshold voltage is applied to between the gate electrode and the source electrode;
a non-current-drift area which is not a substantial current path from the drain electrode to the source electrode in the semiconductor stack; and
a collapse reducing electrode formed discontinuously from the gate electrode on the non-current-drift area in the second nitride semiconductor layer, the collapse reducing electrode being formed to have a substantially same potential as the gate electrode,
wherein the collapse reducing electrode and the second nitride semiconductor layer have a junction surface functioning as an energy barrier having a rectifying effect in a forward direction from the collapse reducing electrode to the second nitride semiconductor layer.

2. The semiconductor device according to claim 1,
wherein the collapse reducing electrode is formed apart from the drain electrode by a minimum distance for obtaining a desired drain voltage resistance.

3. The semiconductor device according to claim 1,
wherein the collapse reducing electrode is formed within the non-current-drift area, between an extension line toward a longitudinal direction of the gate electrode and an extension line toward a longitudinal direction of the drain electrode.

4. The semiconductor device according to claim 1,
wherein, the semiconductor stack has, in plan view, parts which contain active two-dimensional electron gas, the parts being the current-drift area, a part immediately below an entirety of the collapse reducing electrode, and the non-current-drift area between the collapse reducing electrode and the current-drift area.

5. The semiconductor device according to claim 1,
wherein the gate electrode and the collapse reducing electrode mainly include different materials.

6. The semiconductor device according to claim 1,
wherein the collapse reducing electrode is a nitride semiconductor layer.

7. The semiconductor device according to claim 1,
wherein the collapse reducing electrode is an organic semiconductor film.

8. The semiconductor device according to claim 1,
wherein the collapse reducing electrode is an oxide semiconductor layer.

9. The semiconductor device according to claim 6,
wherein the collapse reducing electrode is of a p-conductivity type.

10. The semiconductor device according to claim 1,
wherein the collapse reducing electrode is in Schottky contact with the second nitride semiconductor layer.

11. A semiconductor device, comprising;
a substrate;
a semiconductor stack including:
a first nitride semiconductor layer formed above the substrate; and
a second nitride semiconductor layer formed on the first nitride semiconductor layer and having a band gap larger than a band gap of the first nitride semiconductor layer;
a source electrode and a drain electrode formed apart from each other above a lower surface of the semiconductor stack;
a gate electrode formed between and apart from the source electrode and the drain electrode on the second nitride semiconductor layer,
in plan view,
a current-drift area which is a substantial current path from the drain electrode to the source electrode in the semiconductor stack when a voltage larger than or equal to a threshold voltage is applied to between the gate electrode and the source electrode;
a non-current-drift area which is not a substantial current path from the drain electrode to the source electrode in the semiconductor stack; and
a collapse reducing electrode formed on the non-current-drift area in the second nitride semiconductor layer, the collapse reducing electrode being formed to have a substantially same potential as the gate electrode,
wherein the collapse reducing electrode and the second nitride semiconductor layer have a junction surface functioning as an energy barrier having a rectifying effect in a forward direction from the collapse reducing electrode to the second nitride semiconductor layer, and
in plan view,
the non-current-drift area in the semiconductor stack includes a high resistance area and a low resistance area, the low resistance area being enclosed by the high resistance area and being in contact with the current-drift area located between the drain electrode and the gate electrode and with the collapse reducing electrode.

12. The semiconductor device according to claim 11,
wherein, the semiconductor stack has, in plan view, parts which contain active two-dimensional electron gas, the parts being the current-drift area, a part immediately below an entirety of the collapse reducing electrode, and the non-current-drift area between the collapse reducing electrode and the current-drift area.

13. The semiconductor device according to claim 11,
wherein the high resistance area in the semiconductor stack contains inactive two-dimensional electron gas, and
the low resistance area in the semiconductor stack contains active two-dimensional electron gas.

14. The semiconductor device according to claim 11,
wherein the collapse reducing electrode and the gate electrode mainly include a same material.

15. The semiconductor device according to claim 11,
wherein the gate electrode and the collapse reducing electrode mainly include different materials.

16. The semiconductor device according to claim 11,
wherein the collapse reducing electrode is a nitride semiconductor layer.

17. The semiconductor device according to claim 11,
wherein the collapse reducing electrode is an organic semiconductor film.

18. The semiconductor device according to claim 11,
wherein the collapse reducing electrode is an oxide semiconductor layer.

19. The semiconductor device according to claim 16,
wherein the collapse reducing electrode is of a p-conductivity type.

20. The semiconductor device according to claim 11,
wherein the collapse reducing electrode is in Schottky contact with the second nitride semiconductor layer.
